(19) United States
(12) Patent Application Publication
(10) Pub. No.: US 2026/0090212 A1
(43) Pub. Date: Mar. 26, 2026

(54) DISPLAY DEVICE

(71) Applicant: LG DISPLAY CO., LTD., SEOUL (KR)

(72) Inventor: Kyungha Lee, Seoul (KR)

(21) Appl. No.: 19/311,127

(22) Filed: Aug. 27, 2025

(30) Foreign Application Priority Data
Sep. 24, 2024 (KR) 10-2024-0129295

(51) Int. Cl. H10K 59/122; H10K 59/12; H10K 59/80

(52) U.S. Cl. CPC H10K 59/122; H10K 59/1201; H10K 59/873

(57) ABSTRACT

A display device includes: a substrate including an active area of the display device and a non-active area of the display device excluding the active area; a driving circuit layer disposed on the substrate, the driving circuit layer including: at least one transistor disposed on the active area; and a plurality of insulating layers which are sequentially disposed on the substrate; a light emitting diode layer disposed on the driving circuit layer, the light emitting diode layer including: a light emitting diode connected to the at least one transistor and disposed on the active area; and a bank defining an opening area overlapping the light emitting diode; and an encapsulation layer disposed on the light emitting diode layer. A bumpy pattern is formed on an upper surface of an insulating layer disposed on the top, among the plurality of insulating layers included in the driving circuit layer.

### CROSS-REFERENCE TO RELATED APPLICATIONS

Pursuant to 35 U.S.C. § 119 (a), this application claims the benefit of an earlier filing date and right of priority of Korean Patent Application No. 10-2024-0129295, filed in the Republic of Korea on Sep. 24, 2024, at the Korean Intellectual Property Office, the disclosure of which is hereby incorporated by reference in its entirety.

### TECHNICAL FIELD

The present disclosure relates to a display device.

### BACKGROUND

With the development of information technology, many related technologies have been developed in the field of display devices for visually displaying information, such as text, images, video, or graphical data. A display device is an output device that converts electrical signals into visible light patterns, typically using an array of pixels composed of sub-pixels.

### SUMMARY

According to a first aspect of the present disclosure, a display device is provided. The display device includes: a substrate which includes an active area of the display device and a non-active area of the display device excluding the active area; a driving circuit layer which is disposed on the substrate, the driving circuit layer including: at least one transistor disposed on the active area; and a plurality of insulating layers which are sequentially disposed on the substrate; a light emitting diode layer which is disposed on the driving circuit layer, the light emitting diode layer including: a light emitting diode which is connected to the at least one transistor and is disposed on the active area; and a bank which defines an opening area overlapping the light emitting diode; and an encapsulation layer which is disposed on the light emitting diode layer. A bumpy (e.g., uneven) pattern is formed on an upper surface of an insulating layer disposed on the top, among the plurality of insulating layers included in the driving circuit layer. In other words, the bumpy pattern is formed on an upper surface of an uppermost one of the plurality of insulating layers.

According to a second aspect of the present disclosure, a display device is provided. The display device includes: a substrate which includes an active area of the display device and a non-active area of the display device excluding the active area; a driving circuit layer which is disposed on the substrate, the driving circuit layer including: at least one transistor disposed on the active area; and a plurality of insulating layers which are sequentially disposed on the substrate; a light emitting diode layer which is disposed on the driving circuit layer, the light emitting diode layer including: a light emitting diode which is connected to the at least one transistor and is disposed on the active area; and a bank which defines an opening area overlapping the light emitting diode; and an encapsulation layer which is disposed on the light emitting diode layer. A bumpy (e.g., uneven) pattern is formed on a lower surface of the bank.

Other features of the examples of the present disclosure are included in the detailed description and the accompanying drawings.

According to the examples of the present disclosure, a display device may include a bumpy pattern which is formed on a surface of at least a part of a plurality of insulating layers included in the display device, and which is disposed on a non-active area and/or an active area of the display device. Therefore, in the non-active area and/or the active area, an adhesive strength between the plurality of insulating layers may be enhanced.

Accordingly, in the display device according to the examples of the present disclosure, a film lifting phenomenon and a loss of an insulating layer caused thereby may be suppressed.

The effects according to the present disclosure are not limited to the contents exemplified above, and other effects are included in the present disclosure.

The effects of the present disclosure are not limited to the aforementioned effects, and other effects, which are not mentioned above, will be clearly understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a block diagram illustrating a display device according to examples of the present disclosure;

FIG. 2 is a perspective view illustrating a display device according to examples of the present disclosure;

FIG. 3 is a cross-sectional view illustrating a display device according to examples of the present disclosure;

FIGS. 4A to 4D are process charts illustrating a manufacturing method of a display device according to examples of the present disclosure;

FIG. 5A is a view illustrating an outer peripheral portion of a display device according to a comparative example of the present disclosure;

FIG. 5B is a view illustrating an outer peripheral portion of a display device according to examples of the present disclosure;

FIG. 6 is a cross-sectional view illustrating a display device according to examples of the present disclosure;

FIG. 7 is a cross-sectional view illustrating a display device according to examples of the present disclosure; and

FIG. 8 is a cross-sectional view illustrating a display device according to examples of the present disclosure.

### DETAILED DESCRIPTION

The field of display devices has been rapidly developed and research has continued to improve various performance metrics of display devices, such as thickness and formfactor, weight, and power consumption. A representative example of a display device may include a liquid crystal display device (LCD), a field emission display device (FED), an electro-wetting display device (EWD), and an organic light emitting display device (OLED). An electroluminescent display device, such as an organic light emitting display device, is a self-emitting display device so that a separate light source is not necessary, unlike a liquid crystal display device which typically includes a backlight. Therefore, the electroluminescent display device may be manufactured to have a lighter weight and a smaller thickness than a liquid crystal displace device. Further, since the electroluminescent display device is advantageous not only in terms of power consumption due to low voltage driving, but also in terms of color implementation, response speed, viewing angle, and contrast ratio (CR), it is expected to be utilized in various fields.

An object to be achieved by the present disclosure is to provide a display device with an improved adhesive strength between a plurality of insulating layers. Another object to be achieved by the present disclosure is to provide a display device which suppresses film lifting. Still another object to be achieved by the present disclosure is to provide a display device which suppresses loss of a bank.

Objects of the present disclosure are not limited to the above-mentioned objects, and other objects, which are not mentioned above, may be clearly understood by those skilled in the art from the following descriptions.

Advantages and characteristics of the present disclosure and a method of achieving the advantages and characteristics will be clear by referring to examples described below in detail together with the accompanying drawings. However, the present disclosure is not limited to the examples disclosed herein but will be implemented in various forms. The examples are provided by way of example only so that those skilled in the art can fully understand the disclosures of the present disclosure and the scope of the present disclosure.

The shapes, sizes, ratios, angles, numbers, and the like depicted in the accompanying drawings for describing the examples of the present disclosure are merely illustrative, and the present disclosure is not limited thereto. Further, in the following description of the present disclosure, a detailed explanation of known related technologies may be omitted to avoid unnecessarily obscuring the subject matter of the present disclosure.

The terms such as “including”, “having”, and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, yet another element or layer may be interposed directly on the another element or layer or therebetween.

Although the terms “first”, “second”, and the like are used for describing various components, these components are not confined by these terms. These terms are merely used for distinguishing one component from another component. Therefore, a first component to be mentioned below may be a second component in a technical concept of the present disclosure.

Like reference numerals generally denote like elements throughout the present disclosure.

A size and a thickness of each component illustrated in the accompanying drawings are illustrated for convenience of description only, and the present disclosure is not limited to the size and the thickness of the component illustrated.

The features of various examples of the present disclosure can be partially or entirely adhered to or combined with each other and can be interlocked and operated in technically different ways, and the examples can be carried out independently of or in association with each other.

Hereinafter, display devices according to examples of the present disclosure will be described in detail with reference to the accompanying drawings. A display device according to the examples of the present disclosure may be an electroluminescent display device. The electroluminescent display device may be an organic light emitting diode (OLED) display device, a quantum dot light emitting diode (QD-LED) display device, or an inorganic light emitting diode (ILED) display device.

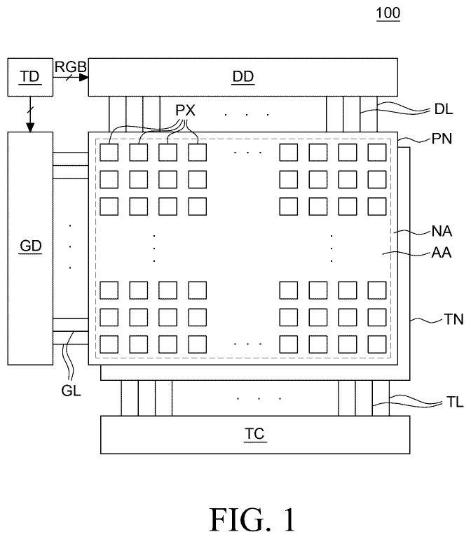

FIG. 1 is a block diagram illustrating a display device 100 according to examples of the present disclosure.

Referring to FIG. 1, the display device 100 according to examples of the present disclosure may include a display panel PN, a gate driver GD, a data driver DD, and a timing controller TD.

The display panel PN may generate images to be provided to the user. The display panel PN may include an active area (or display area) AA in which images are displayed and a non-active area (or non-display area) NA excluding the active area AA.

The active area AA may include a plurality of pixels PX connected to a plurality of data lines DL and a plurality of gate lines GL.

Various signal lines, pads, and the gate driver GD for driving a pixel circuit disposed in a pixel PX may be disposed in the non-active area NA.

The timing controller TD may control the data driver DD and the gate driver GD. For example, the timing controller TD rearranges digital video data input from the outside in accordance with a resolution of the display panel PN to generate the image data RGB and supply the image data to the data driver DD. Further, the timing controller TD generates timing control signals (for example, a data control signal and a gate control signal) to control the data driver DD and the gate driver GD using a control signal input from the outside to supply the timing control signals to the data driver DD and the gate driver GD.

The data driver DD converts image data RGB input from the timing controller TD based on the data control signal supplied from the timing controller TD into the analog data signal (for example, data voltage) to supply the converted analog data signal to the plurality of data lines DL.

The gate driver GD may generate a gate signal based on the gate control signal supplied from the timing controller TD. For example, the gate driver GD generates a gate signal in a row sequential manner to supply the gate signal to the plurality of gate lines GL.

In one example, the display device 100 may further include a touch panel TN and a touch controller TC. According to the example, the touch panel TN and the touch controller TC may be defined as a touch sensor.

In one example, the touch sensor including the touch panel TN and the touch controller TC may be a capacitive type of touch sensor, but is not limited thereto and may be various types of currently known touch sensors.

Each of the timing controller TD and the touch controller TC may be configured by an integrated circuit including circuit elements for driving the display panel PN and the touch panel TN. For example, the timing controller TD and the touch controller TC may be manufactured as separate chips or integrated as a single chip.

In one example, the display panel PN and the touch panel TN may be integrally manufactured. For example, the touch panel TN may be formed in the display panel PN together with the pixels PX or may be formed directly on at least one surface (for example, an upper surface and/or a lower surface) of the display panel PN. In another example, the display panel PN and the touch panel TN may be non-integrally manufactured. For example, the touch panel TN is manufactured separately from the display panel PN to be attached on at least one surface of the display panel PN by a transparent adhesive.

The touch panel TN may include a sensing area. A plurality of touch electrodes TE is disposed on the sensing area and the sensing area is an area in which an input (for example, a touch input) of a user is sensed by the touch panel TN. For example, the sensing area of the touch panel TN may overlap the active area AA.

Further, the touch panel TN may include a non-sensing area. The non-sensing area is an area excluding the sensing area and may overlap the non-active area NA. In the non-sensing area of the touch panel TN, a plurality of touch lines TL and pads which are connected to the plurality of touch electrodes TE may be disposed.

The touch panel TN may include a touch sensor layer including the plurality of touch electrodes TE and the plurality of touch lines TL disposed on the sensing area. When the plurality of touch electrodes TE is driven in response to the touch driving signal supplied from the touch controller TC, the touch panel may detect a touch input generated in the sensing area.

The touch controller TC supplies a touch driving signal from the plurality of touch electrodes TE of the touch panel TN and may receive a sensing signal output from the plurality of touch electrodes TE by the touch driving signal. The touch controller TC analyzes a sensing signal to detect whether a touch input occurs and/or a position thereof.

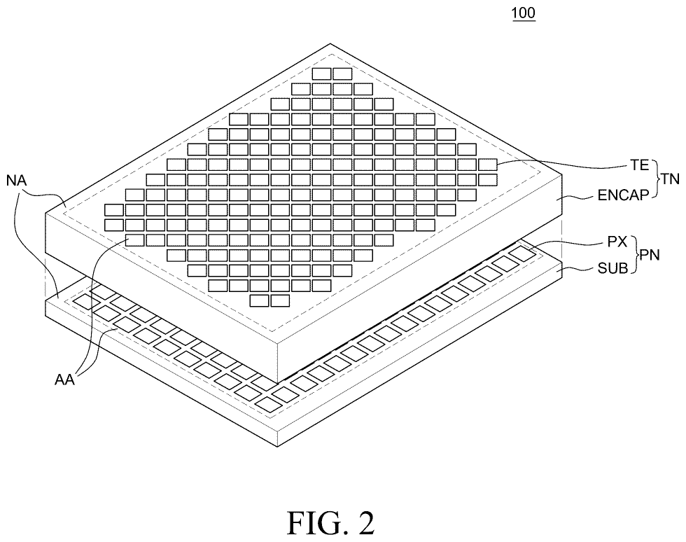

FIG. 2 is a perspective view illustrating the display device 100 according to examples of the present disclosure.

Referring to FIGS. 1 and 2, the display device 100 according to the examples of the present disclosure may include a display panel PN and a touch panel TN disposed on the display panel PN.

The display panel PN may include a substrate SUB and a plurality of pixels PX disposed on the substrate SUB.

The substrate SUB may have an active area AA in which the plurality of pixels PX is disposed to display an image to be supplied to the user, and a non-active area NA in which various signal lines, pads, and a gate driver GD for driving the plurality of pixels PX are disposed.

On the display panel PN in which the plurality of pixels PX are disposed, an encapsulation layer ENCAP which suppresses oxygen or moisture from permeating to the plurality of pixels PX disposed in the display panel PN may be disposed. According to the example, the encapsulation layer ENCAP may be formed by alternately laminating a plurality of inorganic layers and organic layers, but is not limited thereto.

A plurality of touch electrodes TE which detects a position according to the input (for example, a touch input) of the user and generates a signal corresponding thereto may be disposed on the encapsulation layer ENCAP. The encapsulation layer ENCAP and the plurality of touch electrodes TE disposed on the encapsulation layer ENCAP may configure the touch panel TN. According to the example, a structure in which the plurality of touch electrodes TE are disposed on the encapsulation layer ENCAP may be referred to as a touch sensor on encapsulation (TOE). As described above, in the case of the display device 100 according to the examples of the present disclosure, the plurality of touch electrodes TE are disposed on the encapsulation layer ENCAP disposed on the display panel PN so that a separate touch panel does not need to be manufactured. Therefore, a thin thickness of the display device 100 may be implemented.

In one example, the plurality of touch electrodes TE may be disposed on an area of the encapsulation layer ENCAP which overlaps the active area AA of the display panel PN, for example, the sensing area of the touch panel TN. Further, as described with reference to FIG. 1, the plurality of touch lines TL and pads which are connected to the plurality of touch electrodes TE may be disposed on the non-sensing area of the touch panel TN, for example, an area overlapping the non-active area NA of the display panel PN.

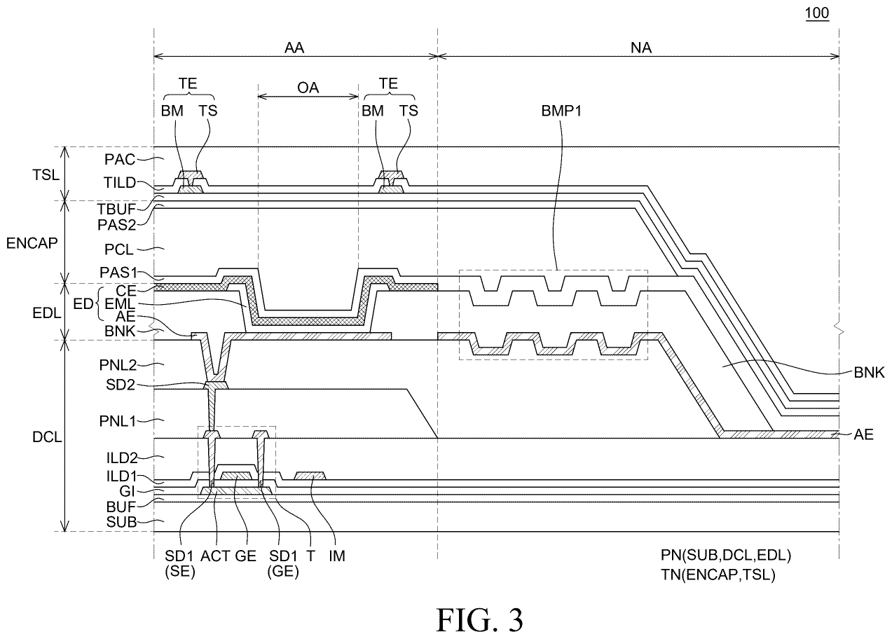

FIG. 3 is a cross-sectional view illustrating a display device 100 according to examples of the present disclosure.

In the meantime, FIG. 3 illustrates an example of a cross-sectional structure of the active area AA and the non-active area NA of the display device 100 which has been described with reference to FIGS. 1 and 2.

Referring to FIGS. 1 and 3, the display device 100 according to the examples of the present disclosure may include a substrate SUB, a driving circuit layer DCL, a light emitting diode layer EDL, an encapsulation layer ENCAP, and a touch sensor layer TSL. According to the example, the substrate SUB, the driving circuit layer DCL, and the light emitting diode layer EDL configure the display panel PN of the display device 100 and the encapsulation layer ENCAP and the touch sensor layer TSL may configure the touch panel TN of the display device 100.

According to the example, the display device 100 may include a first bumpy portion BMP1 disposed in the non-active area NA. For example, the first bumpy portion BMP1 may be defined to include a bumpy pattern formed on a surface of at least a part of the plurality of insulating layers included in the display device 100. An adhesive strength between the plurality of insulating layers included in the display device 100 in the outer peripheral portion of the display device 100 in which the bumpy pattern is formed by the first bumpy portion BMP1, for example, in the non-active area NA may be enhanced. Accordingly, in the display device 100 according to the examples of the present disclosure, the film lifting phenomenon and a loss of the insulating layer thereby in the outer peripheral portion, for example, in the non-active area NA may be suppressed.

The cross-sectional structure of the display device 100 according to the examples of the present disclosure will be described in more detail with reference to FIG. 3. The substrate SUB is a base layer of the display panel PN and may include a plastic material or a glass material.

For example, the substrate SUB may include an opaque or colored polyimide material. For example, the substrate SUB formed of a polyimide material may be formed by hardening a polyimide resin coated with a predetermined thickness on a front surface of a release layer provided on a carrier substrate with a relatively large thickness. In this case, the carrier substrate (for example, a carrier glass substrate) may be separated from the substrate SUB by releasing the release layer using a laser release process. The substrate SUB may further include a back plate which is coupled to a rear surface of the substrate SUB based on a thickness direction thereof. The back plate may maintain the substrate SUB to be flat. For example, the back plate may include a plastic material, and for example, may include a polyethylene terephthalate material. The back plate may be laminated on a rear surface of the substrate SUB which is separated from the carrier glass substrate (for example, the carrier glass substrate).

As another example, the substrate SUB may be a flexible glass substrate. For example, the substrate SUB formed of a glass material may be a thin glass substrate having a thickness of 100 micrometers or smaller or may be a carrier glass substrate etched by a substrate etching process to have a thickness of 100 micrometers or smaller.

As described with reference to FIGS. 1 and 2, the substrate SUB may have an active area AA and a non-active area NA enclosing the active area AA.

The driving circuit layer DCL may be disposed on the substrate SUB.

The driving circuit layer DCL may include at least one transistor T and a plurality of insulating layers. For example, the plurality of insulating layers included in the driving circuit layer DCL may include a buffer layer BUF, a gate insulating layer GI, a first interlayer insulating layer ILD1, a second interlayer insulating layer ILD2, a first planarization layer PNL1, and a second planarization layer PNL2 which are sequentially disposed on the substrate SUB.

The buffer layer BUF may be disposed on the substrate SUB. The buffer layer BUF may serve to protect components (for example, a thin film transistor, etc.) included in the pixel PX from impurities, such as alkali ions leaked from the substrate SUB.

Further, the buffer layer BUF serves to improve an adhesive strength between layers formed thereabove and the substrate SUB and block moisture (H₂O) or oxygen (O₂) permeating through the substrate SUB.

The buffer layer BUF may include an insulating material. For example, the buffer layer BUF may be configured by a single layer or a multi-layer (for example, a double layer) formed of at least one of silicon nitride (SiNx), silicon oxide (SiOx), and silicon oxynitride (SiON). However, the buffer layer BUF may be omitted depending on a structure or a characteristic of the display device 100.

At least one transistor T may be disposed on the buffer layer BUF. At least one transistor T may be disposed in the active area AA of the substrate SUB. In the meantime, at least one transistor T illustrated in FIG. 3 may be a driving transistor which is electrically connected to the light emitting diode of the pixel PX, but is not limited thereto.

At least one transistor T may be disposed in the active area AA. At least one transistor T may include a semiconductor layer ACT, a gate electrode GE, a source electrode SE, and a drain electrode DE which are disposed on the substrate SUB or the buffer layer BUF. In the meantime, in FIG. 3, it is illustrated that at least one transistor T has a top gate structure in which the gate electrode GE is disposed above the semiconductor layer ACT, but the present disclosure is not limited thereto. At least one transistor T may have a bottom gate structure in which the gate electrode GE is located below the semiconductor layer ACT or a double gate structure in which the gate electrode GE is disposed both above and below the semiconductor layer ACT.

The semiconductor layer ACT may be disposed on the substrate SUB or the buffer layer BUF. The semiconductor layer ACT includes a silicon based semiconductor material, an oxide based semiconductor material, or an organic semiconductor material and may have a single layered structure or a double layered structure. Even though it is not illustrated in FIG. 3, according to the example, a light shielding layer for blocking external light incident to the semiconductor layer ACT may be further formed between the buffer layer BUF and the semiconductor layer ACT.

The gate insulating layer GI may be disposed on the buffer layer BUF. For example, the gate insulating layer GI may be disposed on the buffer layer BUF so as to cover the semiconductor layer ACT. The gate insulating layer GI may insulate the semiconductor layer ACT from the gate electrode GE.

The gate insulating layer GI may include an insulating material. For example, the gate insulating layer GI may be formed as a single layer of silicon nitride (SiNx) or silicon oxide (SiOx) which is an inorganic material or a multiple layer of silicon nitride (SiNx) or silicon oxide (SiOx), but it is not limited thereto.

The gate electrode GE may be disposed on the gate insulating layer GI. For example, the gate electrode GE may be disposed on the gate insulating layer GI so as to cover the semiconductor layer ACT.

The gate electrode GE includes a metal material. For example, the gate electrode GE may be formed of a single layer or a multi-layer formed of any one of molybdenum (Mo), aluminum (Al), chrome (Cr), gold (Au), titanium (Ti), nickel (Ni), neodymium (Nd), and copper (Cu) or an alloy thereof, but the material of the gate electrode GE is not limited thereto. According to the example, the gate electrode GE may be formed together with the gate line GL.

The first interlayer insulating layer ILD1 may be disposed on the gate insulating layer GI. For example, the first interlayer insulating layer ILD1 may be disposed on the gate insulating layer GI so as to cover the gate electrode GE. The first interlayer insulating layer ILD1 may insulate the gate electrode GE from an intermediate metal layer IM.

The first interlayer insulating layer ILD1 may be formed of an inorganic material, similar to the buffer layer BUF. For example, the first interlayer insulating layer ILD1 may be configured by a single layer of silicon nitride (SiNx) or silicon oxide (SiOx) which is an inorganic material or a multiple layer of silicon nitride (SiNx) or silicon oxide (SiOx), but it is not limited thereto.

The intermediate metal layer IM may be disposed on the first interlayer insulating layer ILD1. The intermediate metal layer IM is disposed on another metal layer (for example, the gate electrode GE, etc.) with at least one insulating layer therebetween to configure a capacitor (for example, a storage capacitor CST) included in the pixel PX and/or configure various signal lines or pads connected to the pixel PX, but is not limited thereto.

The intermediate metal layer IM may be formed of any one of various metal materials, for example, any one of molybdenum (Mo), aluminum (Al), chrome (Cr), gold (Au), titanium (Ti), nickel (Ni), neodymium (Nd), and copper (Cu) or an alloy of two or more of them, or may be a multiple layer of the above metal materials, but it is not limited thereto.

The second interlayer insulating layer ILD2 may be disposed on the first interlayer insulating layer ILD1. For example, the second interlayer insulating layer ILD2 may be disposed on the first interlayer insulating layer ILD1 so as to cover the intermediate metal layer IM. The second interlayer insulating layer ILD2 may insulate the gate electrode GE from the source electrode SE and the drain electrode DE, together with the first interlayer insulating layer ILD1.

The second interlayer insulating layer ILD2 may be formed of an inorganic material, similar to the buffer layer BUF. For example, the second interlayer insulating layer ILD2 may be configured by a single layer of silicon nitride (SiNx) or silicon oxide (SiOx) which is an inorganic material or a multiple layer of silicon nitride (SiNx) or silicon oxide (SiOx), but it is not limited thereto.

The source electrode SE and the drain electrode DE may be formed on the second interlayer insulating layer ILD2 so as to overlap the semiconductor layer ACT with the gate electrode GE therebetween. For example, the source electrode SE and the drain electrode DE may be disposed so as to be spaced apart from each other on the same layer.

According to the example, the source electrode SE and the drain electrode DE may be formed together with the data line DL. For example, each of the source electrode SE, the drain electrode DE, and the data line DL may be simultaneously formed by the patterning process for the material of the source and drain electrodes. According to the example, the electrode pattern which configures the source electrode SE, the drain electrode DE, and the data line DL may comprise the first metal pattern SD1 formed on the same layer, for example, on the second interlayer insulating layer ILD2.

Each of the source electrode SE and the drain electrode DE may be in contact with the semiconductor layer ACT through a contact hole which passes through the second interlayer insulating layer ILD2, the first interlayer insulating layer ILD1, and the gate insulating layer GI. For example, the source electrode SE is in contact with the source region of the semiconductor layer ACT through a contact hole which passes through the second interlayer insulating layer ILD2, the first interlayer insulating layer ILD1, and the gate insulating layer GI. The drain electrode DE may be in contact with the drain region of the semiconductor layer ACT through a contact hole which passes through the second interlayer insulating layer ILD2, the first interlayer insulating layer ILD1, and the gate insulating layer GI.

The source electrode SE and the drain electrode DE may be formed of a single layer or a multi-layer made of any one of molybdenum (Mo), aluminum (Al), chrome (Cr), gold (Au), titanium (Ti), nickel (Ni), neodymium (Nd), and copper (Cu), or an alloy thereof, but the material of the source electrode SE and the drain electrode DE is not limited thereto.

A first planarization layer PNL1 may be disposed on the second interlayer insulating layer ILD2. For example, the first planarization layer PNL1 may be disposed on the second interlayer insulating layer ILD2 so as to cover the first metal pattern SD1 (for example, a source electrode SE and a drain electrode DE). The first planarization layer PNL1 may provide a flat surface on the transistor T.

The first planarization layer PNL1 may be configured by a single layer or a plurality of layers and may be formed of an organic material. For example, the first planarization layer PNL1 may be formed of an organic film, such as acryl resin, epoxy resin, phenolic resin, polyamide resin, or polyimide resin, but the material of the first planarization layer PNL1 is not limited thereto.

According to the example, the first planarization layer PNL1 is formed in the active area AA, but is not formed in the non-active area NA, but is not limited thereto.

A second metal pattern SD2 may be disposed on the first planarization layer PNL1. The second metal pattern SD2 may be electrically connected to the source electrode SE or the drain electrode DE of the transistor T through a through hole which passes through the first planarization layer PNL1.

The second metal pattern SD2 may include the same material as the first metal pattern SD1, for example, the source electrode SE and the drain electrode DE of the transistor T. For example, the second metal pattern SD2 may be formed of a single layer or a multi-layer made of any one of molybdenum (Mo), aluminum (Al), chrome (Cr), gold (Au), titanium (Ti), nickel (Ni), neodymium (Nd), and copper (Cu) or an alloy thereof, but is not limited thereto.

The second planarization layer PNL2 may be disposed on the first planarization layer PNL1. For example, the second planarization layer PNL2 may be disposed on the first planarization layer PNL1 so as to cover the second metal pattern SD2. The second planarization layer PNL2 may provide a flat surface on the transistor T and the second metal pattern SD2. The second planarization layer PNL2 may be formed of the same material as the first planarization layer PNL1, but is not limited thereto.

According to an example, among the plurality of insulating layers included in a driving circuit layer DCL, an insulating layer disposed on the top, for example, the second planarization layer PNL2 may include a bumpy pattern which is formed in an area in which the first bumpy portion BMP1 is formed as an outer peripheral portion of the display device 100. For example, the bumpy pattern may be disposed on an upper surface of the second planarization layer PNL2. For example, the bumpy pattern formed on the upper surface of the second planarization layer PNL2 may be disposed in the non-active area NA.

The bumpy pattern formed on the upper surface of the second planarization layer PNL2 may include at least one protruding portion protruding in one direction and at least one dented portion which is dented in a direction opposite to the one direction. According to the example, as illustrated in FIG. 3, the protruding portion and the dented portion included in the bumpy pattern which is formed on the upper surface of the second planarization layer PNL2 may have a trapezoidal shape, but it is not limited thereto. Therefore, the protruding portion and the dented portion included in the bumpy pattern which is formed on the upper surface of the second planarization layer PNL2 may have various shapes, such as a rectangular shape, a square shape, a semi-circular shape, or a semi-oval shape.

In the meantime, in FIG. 3, it is illustrated that the bumpy pattern formed on the upper surface of the second planarization layer PNL2 includes two protruding portions and three dented portions, but the number of protruding portions and dented portions are not limited thereto.

The light emitting diode layer EDL may be disposed on the driving circuit layer DCL, for example, on the second planarization layer PNL2 of the driving circuit layer DCL. The light emitting diode layer EDL may include a light emitting diode ED and a bank BNK.

The bank BNK may be disposed on the driving circuit layer DCL, for example, on the second planarization layer PNL2. The bank BNK is disposed on the second planarization layer PNL2 to define an opening area OA in the active area AA. The opening area OA may be disposed so as to overlap the light emitting diode ED. In the meantime, the bank BNK may be defined as a pixel definition film and the opening area OA may be defined as an emission area. The bank BNK may be formed not only in the active area AA, but also in the non-active area NA.

The bank BNK may include an organic insulating material. For example, the bank BNK may be formed of polyimide, acryl, or benzocyclobutene (BCB) resin, but it is not limited thereto.

In one example, the bank BNK may include a bumpy pattern formed in an area in which the first bumpy portion BMP1 is formed as an outer peripheral portion of the display device 100. For example, the bumpy pattern may be formed on an upper surface and a lower surface of the bank BNK. For example, the bumpy pattern formed on the upper surface and the lower surface of the bank BNK may be disposed in the non-active area NA.

The bumpy pattern formed on the lower surface of the bank BNK may be formed so as to correspond to the bumpy pattern formed on an upper surface of the second planarization layer PNL2. For example, the bumpy pattern formed on the lower surface of the bank BNK has a dented portion so as to correspond to the protruding portion of the bumpy pattern formed on the upper surface of the second planarization layer PNL2. Further, the bumpy pattern formed on the lower surface of the bank BNK has a protruding portion so as to correspond to the dented portion of the bumpy pattern formed on the upper surface of the second planarization layer PNL2. That is, the bumpy pattern formed on the upper surface of the second planarization layer PNL2 and the bumpy pattern formed on the lower surface of the bank BNK are disposed to be engaged with each other so that the adhesive strength between the second planarization layer PNL2 and the bank BNK may be enhanced. Accordingly, the film lifting phenomenon between the second planarization layer PNL2 and the bank BNK in the outer peripheral portion of the display device 100, for example, in the non-active area NA is suppressed and the loss of the bank BNK due to the film lifting phenomenon may be suppressed.

Further, the bumpy pattern formed on the upper surface of the bank BNK may include at least one protruding portion protruding in one direction and at least one dented portion which is dented in a direction opposite to the one direction. According to the example, as illustrated in FIG. 3, the protruding portion and the dented portion included in the bumpy pattern which is formed on the upper surface of the bank BNK may have a trapezoidal shape, but it is not limited thereto. Therefore, the protruding portion and the dented portion included in the bumpy pattern which is formed on the upper surface of the bank BNK may have various shapes, such as a rectangular shape, a square shape, a semi-circular shape, or a semi-oval shape.

In the meantime, in FIG. 3, it is illustrated that the bumpy pattern formed on the upper surface of the bank BNK includes two protruding portions and three dented portions, but the number of protruding portions and dented portions are not limited thereto.

The light emitting diode ED is disposed above the transistor T in the active area AA to be connected to the transistor T and may include a first electrode AE, an emission layer EML, and a second electrode CE. In the meantime, the first electrode AE may be defined as an anode electrode or the pixel driving electrode and the second electrode CE may be defined as a cathode electrode or a common electrode.

The first electrode AE may be disposed on the second planarization layer PNL2. For example, a part of the first electrode AE may be disposed on the second planarization layer PNL2 so as to overlap at least a part of the opening area OA of the active area AA. Further, the remaining part of the first electrode AE may be disposed on the second planarization layer PNL2 so as to overlap at least a part of an area excluding the opening area OA of the active area AA.

The first electrode AE disposed in the active area AA may be electrically connected to the second metal pattern SD2 through a contact hole which passes through the second planarization layer PNL2. Accordingly, the first electrode AE may be in contact with the source electrode SE or the drain electrode DE of the transistor T through the second metal pattern SD2. In this case, a remaining edge part excluding a part of the first electrode AE which overlaps the opening area OA of the active area AA may be covered by the bank BNK. The bank BNK covers the edge of the first electrode AE to define the opening area OA in the active area AA.

According to the example, at least a part of the first electrode AE may also be disposed in the non-active area NA. For example, the first electrode AE disposed in the non-active area NA is disposed between the second planarization layer PNL2 and the bank BNK and may configure a signal line and/or a power line connected to the pixel PX.

The first electrode AE may include a metal material having a high reflectance. For example, the first electrode AE may be formed with a multi-layered structure, such as a lamination structure (Ti/Al/Ti) of aluminum (Al) and titanium (Ti), a lamination structure (ITO/AI/ITO) of aluminum (Al) and ITO, APC alloy (Ag/Pd/Cu), a lamination structure (ITO/APC/ITO) of the APC alloy and ITO. Further, the first electrode AE may include a single layer structure formed of any one selected from silver (Ag), aluminum (Al), molybdenum (Mo), gold (Au), magnesium (Mg), calcium (Ca), and barium (Ba) or an alloy material of two or more of them, but is not limited thereto.

The emission layer EML may be formed to cover at least a part of the first electrode AE and at least a part of the bank BNK.

The emission layer EML may include a first light emitting unit and a second light emitting unit to emit white light by mixing first light and second light. Here, the first light emitting unit emits first light and may include any one of a blue light emitting unit, a green light emitting unit, a red light emitting unit, a yellow light emitting unit, and a yellowish green light emitting unit. The second light emitting unit may include a light emitting unit which emits second light which is a complementary color of the first light, among the blue light emitting unit, the green light emitting unit, the red light emitting unit, the yellow light emitting unit, and the yellowish green light emitting unit.

As another example, the emission layer EML may include any one of a blue light emitting unit, a green light emitting unit, and a red light emitting unit to emit color light corresponding to a color set in the pixel PX. For example, the emission layer EML may include any one of an organic emission layer, an inorganic emission layer and a quantum dot emission layer or a laminated or mixed structure of an organic emission layer or an inorganic emission layer and the quantum dot emission layer.

However, the light emitting unit included in the emission layer EML is not limited thereto and the light emitting unit may be formed in various forms.

Additionally, the light emitting diode ED may further include a functional layer to improve a luminous efficiency and/or a lifespan of the emission layer EML.

The second electrode CE may be disposed on the emission layer EML. The second electrode CE may be formed to be electrically connected to the emission layer EML. For example, the second electrode CE may be formed in the entire active area AA to be commonly connected to the emission layer EML.

The second electrode CE may include a transparent conductive material or a transflective conductive material which transmits light. When the second electrode CE is formed of a transflective conductive material, an emission efficiency of light emitted from the light emitting diode ED may be increased by a micro cavity structure. For example, the transflective conductive material may include magnesium (Mg), silver (Ag), or an alloy of magnesium (Mg) and silver (Ag).

Additionally, a capping layer which improves a light emission efficiency by adjusting a refractive index of the light emitted from the light emitting diode ED may be further formed on the second electrode CE.

The encapsulation layer ENCAP may be disposed on the light emitting diode layer EDL, for example, on the second electrode CE of the light emitting diode layer EDL. The encapsulation layer ENCAP may suppress moisture (H₂O) and oxygen (O₂) from permeating to the pixel PX (for example, light emitting diode ED).

The encapsulation layer ENCAP may include a first inorganic encapsulation layer PAS1, an organic encapsulation layer PCL on the first inorganic encapsulation layer PAS1, and a second inorganic encapsulation layer PAS2 on the organic encapsulation layer PCL.

The first inorganic encapsulation layer PAS1 and the second inorganic encapsulation layer PAS2 may block the permeation of moisture or oxygen. For example, the first inorganic encapsulation layer PAS1 and the second inorganic encapsulation layer PAS2 may include an inorganic material, such as silicon nitride, aluminum nitride, zirconium nitride, titanium nitride, hafnium nitride, tantalum nitride, silicon oxide, aluminum oxide, or titanium nitride. The first inorganic encapsulation layer PAS1 and the second inorganic encapsulation layer PAS2 may be formed by a chemical vapor deposition process or an atomic layer deposition process.

The organic encapsulation layer PCL may be disposed between the first inorganic encapsulation layer PAS1 and the second inorganic encapsulation layer PAS2. For example, the organic encapsulation layer PCL is disposed on the first inorganic encapsulation layer PAS1 to planarize a surface of the inorganic encapsulation layer PAS1.

The organic encapsulation layer PCL may be formed with a thickness relatively larger than that of the first inorganic encapsulation layer PAS1 and/or the second inorganic encapsulation layer PAS2 to cover particles which may be generated during the manufacturing process of the display device 100. The organic encapsulation layer PCL may include an organic material such as silicon oxy carbon (SiOCz) acryl or epoxy-based resin. The organic encapsulation layer PCL may be formed by a coating process, such as an inkjet coating process or a slit coating process.

In the meantime, even though it is not illustrated in FIG. 3, in order to suppress the collapse of the encapsulation layer ENCAP, one or more dams may be disposed at an end portion of the inclined surface of the encapsulation layer ENCAP or in the vicinity thereof. One or more dams may be present in a boundary portion of the active area AA and the non-active area NA or in the vicinity of the boundary portion, but is not limited thereto.

In one example, the first inorganic encapsulation layer PAS1 may include a bumpy pattern formed in an area in which the first bumpy portion BMP1 is formed as an outer peripheral portion of the display device 100. For example, the bumpy pattern may be formed on an upper surface and a lower surface of the first inorganic encapsulation layer PAS1. For example, the bumpy pattern formed on the upper surface and the lower surface of the first inorganic encapsulation layer PAS1 may be disposed in the non-active area NA.

The bumpy pattern formed on the lower surface of the first inorganic encapsulation layer PAS1 may be formed so as to correspond to the bumpy pattern formed on the upper surface of the bank BNK. For example, the bumpy pattern formed on the lower surface of the first inorganic encapsulation layer PAS1 so as to correspond to the protruding portion of the bumpy pattern formed on the upper surface of the bank BNK has a dented portion. Further, the bumpy pattern formed on the lower surface of the first inorganic encapsulation layer PAS1 so as to correspond to the dented portion of the bumpy pattern formed on the upper surface of the bank BNK may have a protruding portion. That is, the bumpy pattern formed on the upper surface of the bank BNK and the bumpy pattern formed on the lower surface of the first inorganic encapsulation layer PAS1 may be disposed to be engaged with each other so that the adhesive strength of the bank BNK and the first inorganic encapsulation layer PAS1 may be enhanced. Accordingly, the film lifting phenomenon between the bank BNK and the first inorganic encapsulation layer PAS1 in the outer peripheral portion of the display device 100, for example, in the non-active area NA is suppressed and the loss of the bank BNK due to the film lifting phenomenon may be suppressed.

Further, the bumpy pattern formed on the upper surface of the first inorganic encapsulation layer PAS1 may include at least one protruding portion protruding in one direction and at least one dented portion which is dented in a direction opposite to the one direction. According to the example, as illustrated in FIG. 3, the protruding portion and the dented portion included in the bumpy pattern which is formed on the upper surface of the first inorganic encapsulation layer PAS1 has a trapezoidal shape, but it is not limited thereto. Therefore, the protruding portion and the dented portion included in the bumpy pattern which is formed on the upper surface of the first inorganic encapsulation layer PAS1 may have various shapes, such as a rectangular shape, a square shape, a semi-circular shape, or a semi-oval shape.

In the meantime, in FIG. 3, it is illustrated that the bumpy pattern formed on the upper surface of the first inorganic encapsulation layer PAS1 includes two protruding portions and three dented portions, but the number of protruding portions and dented portions are not limited thereto.

The touch sensor layer TSL may be disposed on the encapsulation layer ENCAP, for example, on the second inorganic encapsulation layer PAS2. The touch sensor layer TSL includes a touch buffer layer TBUF, a touch insulating layer TILD, and a plurality of touch electrodes TE and may sense an input (for example, a touch input) of a user in the active area AA.

The touch buffer layer TBUF may be disposed so as to cover the encapsulation layer ENCAP. The touch buffer layer TBUF may supply a flat surface to the encapsulation layer ENCAP. For example, as illustrated in FIG. 3, the touch buffer layer TBUF may be entirely formed in the active area AA and the non-active area NA so as to cover the encapsulation layer ENCAP.

The touch buffer layer TBUF may be formed of an inorganic material or an organic material. For example, the touch buffer layer TBUF includes an inorganic material, such as silicon nitride SiNx or silicon oxynitride SiON, but the material of the touch buffer layer is not limited thereto. The touch buffer layer TBUF may be formed by a chemical vapor deposition method.

Each of the plurality of touch electrodes TE is disposed in the active area AA and may include a bridge pattern BM and a sensing pattern TS.

Each of the plurality of bridge patterns BM included in the plurality of touch electrodes TE may be disposed on the touch buffer layer TBUF. For example, each of the plurality of bridge patterns BM may be disposed on the touch buffer layer TBUF so as to overlap the bank BNK disposed in the active area AA. For example, each of the plurality of bridge patterns BM may be disposed so as to overlap an area of the active area AA excluding the opening area OA.

The touch insulating layer TILD may be disposed on the touch buffer layer TBUF. For example, the touch insulating layer TILD may be disposed on the touch buffer layer TBUF so as to cover the bridge pattern BM.

The touch insulating layer TILD may include an inorganic material, for example, silicon oxide (SiOx) or silicon nitride (SiNx), but the material of the touch insulating layer TILD is not limited thereto.

Each of the plurality of sensing patterns TS included in the plurality of touch electrodes TE may be disposed on the touch insulating layer TILD. For example, each of the plurality of sensing patterns TS may be disposed on the touch insulating layer TILD so as to overlap the bank BNK disposed in the active area AA. For example, each of the plurality of sensing patterns TS may be disposed so as to overlap an area of the active area AA excluding the opening area OA. Therefore, each of the plurality of sensing patterns TS may be disposed so as to overlap each of the plurality of bridge patterns BM.

Each of the plurality of sensing patterns TS may be electrically connected to a respective one of the plurality of bridge patterns BM through a contact hole which passes through the touch insulating layer TILD. Accordingly, the plurality of sensing patterns TS and the plurality of bridge patterns BM are electrically connected to form the plurality of touch electrodes TE.

In the meantime, even though it is not illustrated in FIG. 3, in the non-active area NA, a routing line extending the touch electrode TE disposed at the outermost periphery of the active area AA to the touch pad disposed in the non-active area NA may be disposed.

In the meantime, even though in FIG. 3, a touch on encapsulation (TOE) in which the touch sensor layer TSL is located above the encapsulation layer ENCAP is illustrated, the structure of the touch sensor layer TSL is not limited thereto.

Referring to FIG. 3, the touch protection layer PAC may be disposed above the touch sensor layer TSL. The touch protection layer PAC may be disposed so as to cover components included in the touch sensor layer TSL, for example, the plurality of touch electrodes TE.

The touch protection layer PAC is formed of an organic material and may planarize an upper portion of the touch sensor layer TSL, but is not limited thereto.

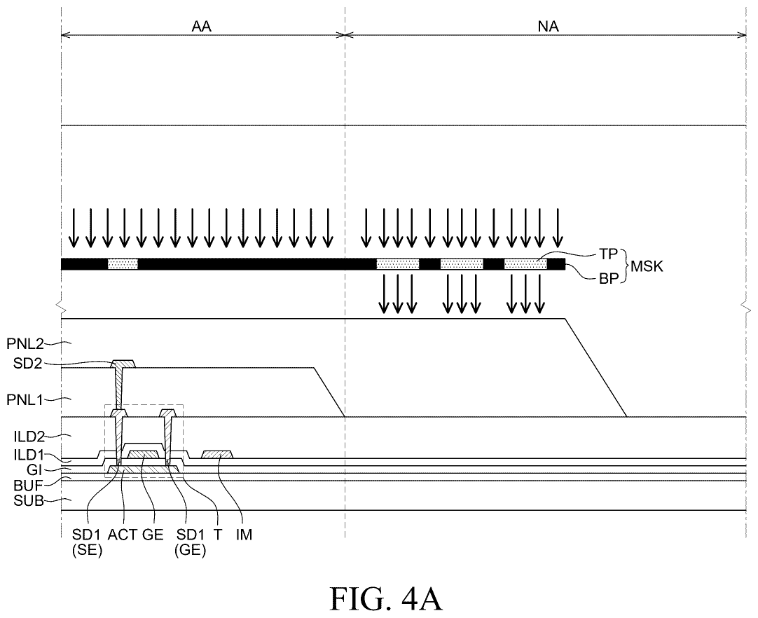

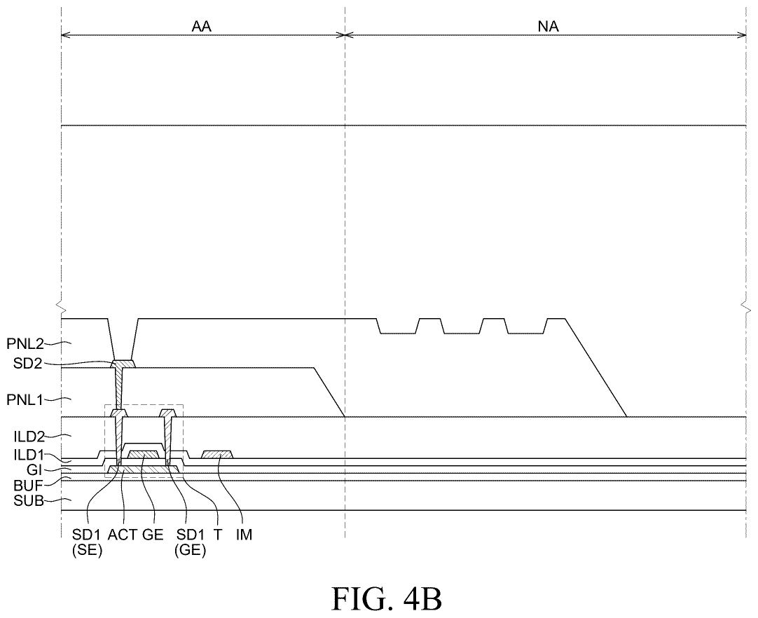

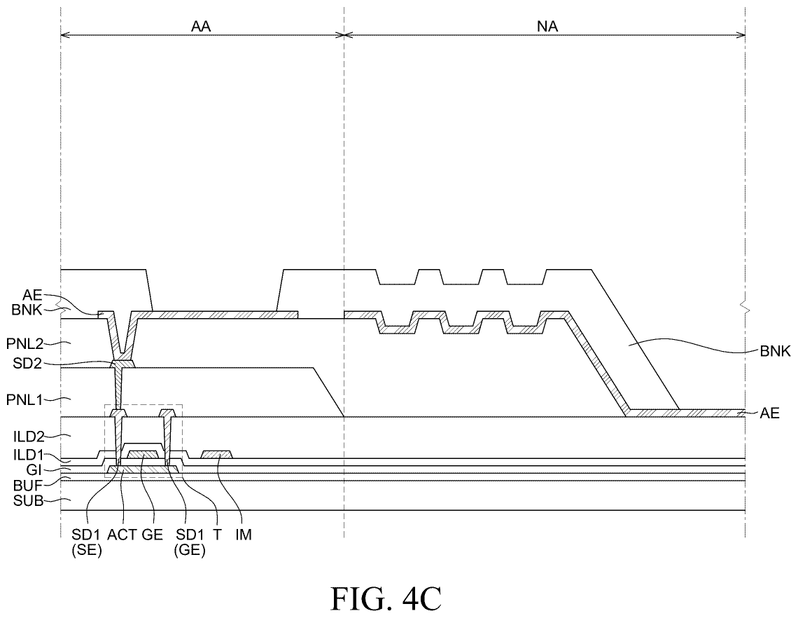

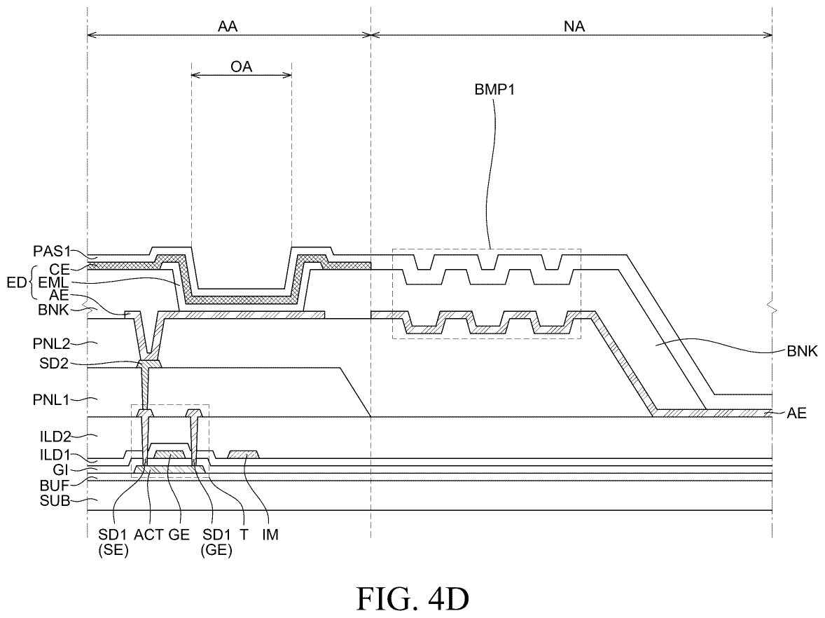

FIGS. 4A to 4D are process charts illustrating a manufacturing method of a display device 100 according to examples of the present disclosure.

In the meantime, in FIGS. 4A to 4D, the manufacturing process of the display device 100 according to the examples of the present disclosure which has been described with reference to FIGS. 1 to 3 are illustrated in cross-sectional views. For example, in FIGS. 4A to 4D, a manufacturing method of the display device 100 according to the example of the present disclosure which has been described with reference to FIGS. 1 to 3 is sequentially illustrated. For convenience of description, the description will be made based on the cross-sectional view of the display device 100 which has been described with reference to FIG. 3.

In the meantime, for the convenience of description, description which overlaps the description which has been made with reference to FIGS. 1 to 3 will not be repeated.

In the meantime, in FIGS. 4A to 4D, in the cross-sectional structure of the display device 100 according to the example of the present disclosure, a manufacturing process of a display device 100 for forming a first bumpy portion BMP1 on an outer peripheral portion of the display device 100, for example, in the non-active area NA will be mainly described.

First, referring to FIG. 4A, at least a part of the second planarization layer PNL2 in the non-active area NA is patterned using a mask MSK to form a bumpy pattern on an upper surface of the second planarization layer PNL2.

For example, after coating a photo resist on the second planarization layer PNL2 disposed in the non-active area NA, at least a part of the second planarization layer PNL2 is removed using the mask MSK to form a bumpy pattern on the upper surface of the second planarization layer PNL2 disposed in the non-active area NA.

In one example, the mask MSK may be a half-tone mask. For example, the mask MSK may include a light shielding portion BP and a light transmitting portion TP (or a semi-transmitting portion). The light shielding portion BP may not allow most of light to pass through. The light transmitting portion TP may have a light transmittance higher than that of the light shielding portion BP. For example, the light transmitting portion TP may transmit a part of light. The mask MSK is configured by a plurality of light shielding portions BP and a plurality of light transmitting portions TP.

As described above, the second planarization layer PNL2 is exposed with different amounts of exposed lights using the mask MSK including the plurality of light shielding portions BP and the plurality of light transmitting portions TP and at least a part of the second planarization layer PNL2 may be removed by a development process. An amount of removed second planarization layer PNL2 varies depending on the amount of exposed light so that the second planarization layer PNL2 is patterned to have a different thickness in different parts.

In the meantime, the mask MSK may further include a light transmitting portion TP which is located in a part of the second planarization layer PNL2 disposed in the active area AA which overlaps the second metal pattern SD2 so as to expose the second metal pattern SD2 corresponding to the active area AA.

Next, referring to FIGS. 4A and 4B, the second planarization layer PNL2 may be formed such that a part exposed by the light transmitting portion TP of the mask MSK is thinner than a part exposed by the light shielding portion BP of the mask MSK. Accordingly, the bumpy pattern may be formed on an upper surface of the second planarization layer PNL2 in the non-active area NA.

Further, at least a part of the second planarization layer PNL2 is removed by the light transmitting portion TP of the mask MSK disposed in the active area AA to expose the second metal pattern SD2.

Next, referring to FIG. 4C, the first electrode AE is provided on the second planarization layer PNL2 and the bank BNK may be provided on the second planarization layer PNL2 so as to cover at least a part of the first electrode AE. Here, as described with reference to FIG. 3, a bumpy pattern may be formed on each of the upper surface and the lower surface of the bank BNK. For example, the bumpy pattern formed on the lower surface of the bank BNK may be formed so as to correspond to the bumpy pattern formed on the upper surface of the second planarization layer PNL2. Further, substantially similar to or the same as the bumpy pattern formed on the upper surface of the second planarization layer PNL2 which has been described with reference to FIGS. 4A and 4B, a bumpy pattern may be formed on the upper surface of the bank BNK using a half tone mask.

Next, referring to FIG. 4D, the emission layer EML is provided so as to cover at least a part of the first electrode AE and at least a part of the bank BNK and the second electrode CE formed on the entire active area AA may be provided on the emission layer EML.

Further, the first inorganic encapsulation layer PAS1 is provided on the bank BNK and the second electrode CE. Here, as described with reference to FIG. 3, a bumpy pattern may be formed on each of the upper surface and the lower surface of the first inorganic encapsulation layer PAS1. For example, the bumpy pattern formed on the lower surface of the first inorganic encapsulation layer PAS1 may be formed so as to correspond to the bumpy pattern formed on the upper surface of the bank BNK. Further, substantially similar to or the same as the bumpy pattern formed on the upper surface of the second planarization layer PNL2 which has been described with reference to FIGS. 4A and 4B, a bumpy pattern may be formed on the upper surface of the first inorganic encapsulation layer PAS1 using a half tone mask.

Accordingly, the first bumpy portion BMP1 may be formed on the outer peripheral portion of the display device 100, for example, in the non-active area NA.

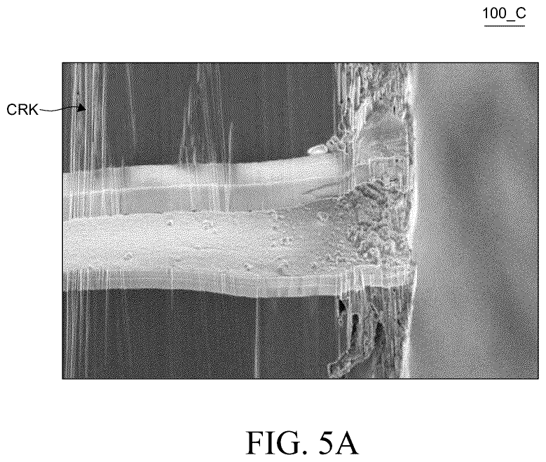

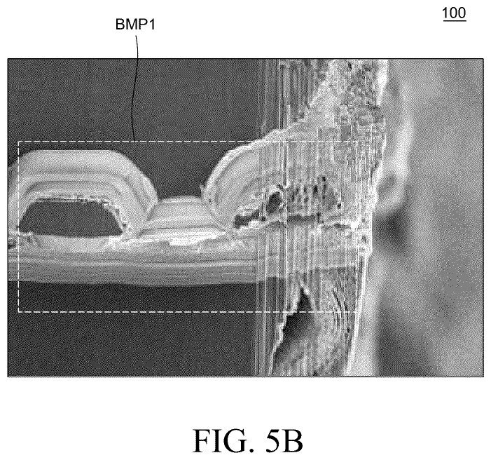

FIG. 5A is a view illustrating an outer peripheral portion of a display device 100_C according to a comparative example of the present disclosure.

FIG. 5B is a view illustrating an outer peripheral portion of a display device 100 according to examples of the present disclosure.

In the meantime, FIG. 5A is a microscopic photograph illustrating the outer peripheral portion of the display device 100_C according to a comparative example of the present disclosure in which a bumpy portion (bumpy pattern) is not formed in the outer peripheral portion (for example, a non-active area). FIG. 5B is a microscopic photograph illustrating the outer peripheral portion of the display device 100 according to an example of the present disclosure in which a first bumpy portion BMP1 is formed in the outer peripheral portion (for example, a non-active area).

First, referring to FIG. 5A, a separate bumpy portion (bumpy pattern) is not formed between the plurality of insulating layers included in the display device 100_C according to the comparative example of the present disclosure. Accordingly, the adhesive strength between the plurality of insulating layers included in the display device 100_C according to the comparative example of the present disclosure is relatively weak so that when an external force is applied to the display device 100_C, cracks may be caused. Accordingly, the film lifting phenomenon occurs between the plurality of insulating layers included in the display device 100_C according to the comparative example of the present disclosure, which causes loss of some insulating layers (for example, the bank).

In contrast, referring to FIG. 5B, a first bumpy portion BMP1 may be formed between the plurality of insulating layers included in the display device 100 according to the examples of the present disclosure. Accordingly, the adhesive strength between the plurality of insulating layers included in the display device 100 according to the examples of the present disclosure is enhanced. Therefore, even though the external force is applied to the display device 100, the crack is not caused and the film lifting phenomenon between the plurality of insulating layers may be suppressed. Therefore, the loss of the insulating layer (for example, a bank BNK) included in the display device 100 may be suppressed.

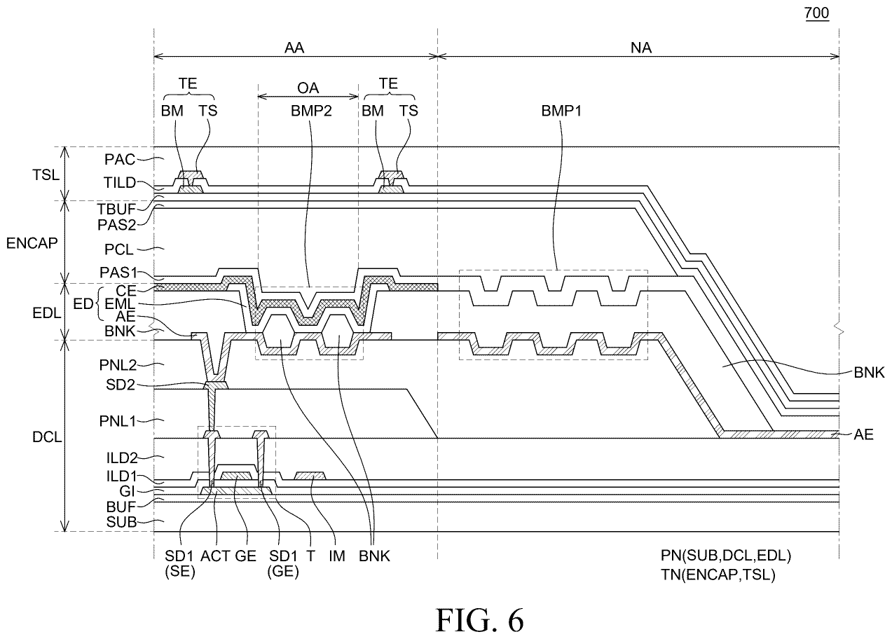

FIG. 6 is a cross-sectional view illustrating a display device 700 according to examples of the present disclosure. FIG. 6 illustrates a modified example of the display device 100 which has been described with reference to FIG. 3 with respect to the second bumpy portion BMP2 so that a redundant description will not be repeated.

Referring to FIG. 6, the display device 700 according to the examples of the present disclosure may include a substrate SUB, a driving circuit layer DCL, a light emitting diode layer EDL, an encapsulation layer ENCAP, and a touch sensor layer TSL.

According to the example, the display device 700 may include a first bumpy portion BMP1 disposed in the non-active area NA and a second bumpy portion BMP2 disposed in the active area AA. For example, the first bumpy portion BMP1 may be defined to include a bumpy pattern formed on a surface of at least a part of the plurality of insulating layers included in the display device 700. Further, the second bumpy portion BMP2 may be defined to include a bumpy pattern formed on a surface of at least a part of the plurality of insulating layers included in the display device 700. An adhesive strength between the plurality of insulating layers included in the display device 700 in the outer peripheral portion of the display device 700 in which the bumpy pattern is formed by the first bumpy portion BMP1, for example, in the non-active area NA may be enhanced. Further, the adhesive strength between the plurality of insulating layers included in the display device 700 is enhanced in the active area AA by the second bumpy portion BMP2 formed in the active area AA so that the shock resistance of the display device 700 may be more enhanced. Accordingly, in the display device 700 according to the examples of the present disclosure, the film lifting phenomenon and a loss of the insulating layer thereby not only in the outer peripheral portion, for example, in the non-active area NA, but also inside, for example, in the entire active area AA may be suppressed.

To be more specific, among the plurality of insulating layers included in a driving circuit layer DCL, an insulating layer disposed on the top, for example, the second planarization layer PNL2 may include a bumpy pattern which is formed in an area in which the second bumpy portion BMP2 is formed. For example, the bumpy pattern may be formed on an upper surface of the second planarization layer PNL2 in the active area AA. For example, the bumpy pattern formed on the upper surface of the second planarization layer PNL2 in the active area AA may include at least one protruding portion and at least one dented portion.

Further, the bank BNK may include a bumpy pattern formed in an area in which the second bumpy portion BMP2 is formed. For example, the bumpy pattern may be formed on an upper surface and a lower surface of the bank BNK in the active area AA. For example, the bumpy pattern formed on the upper surface and the lower surface of the bank BNK in the active area AA may include at least one protruding portion and at least one dented portion.

Similarly, the first inorganic encapsulation layer PAS1 may include a bumpy pattern formed in an area in which the second bumpy portion BMP2 is formed. For example, the bumpy pattern may be formed on an upper surface and a lower surface of the first inorganic encapsulation layer PAS1 in the active area AA. For example, the bumpy pattern formed on the upper surface and the lower surface of the first inorganic encapsulation layer PAS1 in the active area AA may include at least one protruding portion and at least one dented portion.

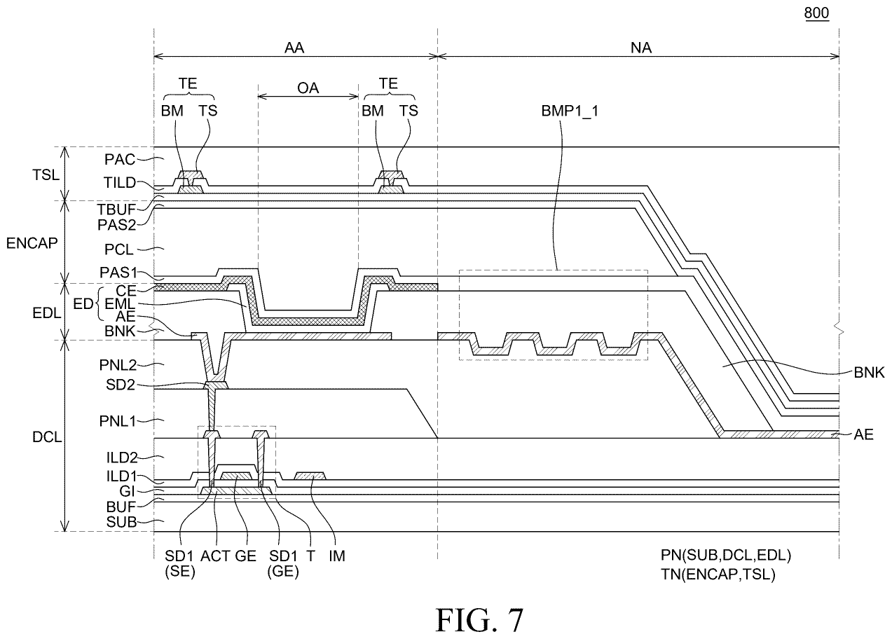

FIG. 7 is a cross-sectional view illustrating a display device 800 according to examples of the present disclosure. FIG. 7 illustrates a modified embodiment for the display device 100 which has been described with reference to FIG. 3 with respect to a shape of a first bumpy portion BMP1_1 so that a redundant description will not be repeated.

Referring to FIG. 7, the display device 800 according to the examples of the present disclosure may include a substrate SUB, a driving circuit layer DCL, a light emitting diode layer EDL, an encapsulation layer ENCAP, and a touch sensor layer TSL.

According to the example, the display device 800 may include a first bumpy portion BMP1_1 disposed in the non-active area NA. For example, the first bumpy portion BMP1_1 may be defined to include a bumpy pattern formed on a surface of at least a part of the plurality of insulating layers included in the display device 800. An adhesive strength between the plurality of insulating layers included in the display device 800 in the outer peripheral portion of the display device 800 in which the bumpy pattern is formed by the first bumpy portion BMP1_1, for example, in the non-active area NA may be enhanced. Accordingly, in the display device 800 according to the examples of the present disclosure, the film lifting phenomenon and a loss of the insulating layer thereby in the outer peripheral portion, for example, in the non-active area NA may be suppressed.

To be more specific, as illustrated in FIG. 7, among the plurality of insulating layers included in a driving circuit layer DCL, an insulating layer disposed on the top, for example, the second planarization layer PNL2 may include a bumpy pattern which is formed in an area in which the first bumpy portion BMP1_1 is formed. For example, the bumpy pattern may be formed on an upper surface of the second planarization layer PNL2 in the non-active area NA. For example, the bumpy pattern formed on the upper surface of the second planarization layer PNL2 in the non-active area NA may include at least one protruding portion and at least one dented portion. Accordingly, as described with reference to FIG. 3, the bank BNK may include a bumpy pattern formed in an area in which the first bumpy portion BMP1_1 is formed. For example, the bumpy pattern is formed on a lower surface of the bank BNK in the non-active area NA.

According to the example, the bank BNK included in the display device 800 of FIG. 7 may include a flat upper surface. Accordingly, the bumpy pattern for enhancing the adhesive strength between the upper surface of the second planarization layer PNL2 and the lower surface of the bank BNK may be compensated by the flat upper surface of the bank BNK.

In the meantime, the lower surface and the upper surface of the first inorganic encapsulation layer PAS1 disposed on the bank BNK may also have flat surfaces along the upper surface of the bank BNK.

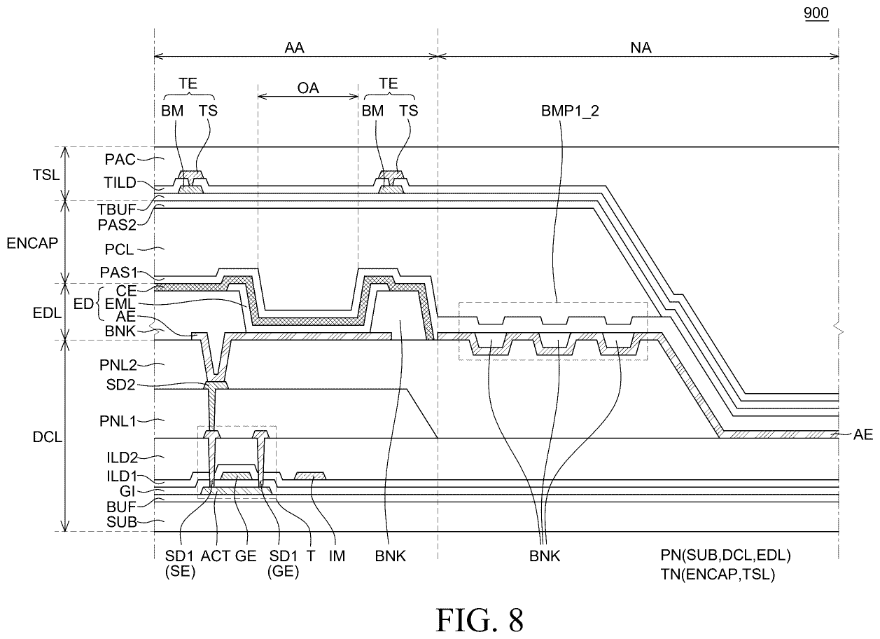

FIG. 8 is a cross-sectional view illustrating a display device 900 according to examples of the present disclosure. FIG. 8 illustrates a modified embodiment for the display device 100 which has been described with reference to FIG. 3 with respect to a shape of a first bumpy portion BMP1_2 so that a redundant description will not be repeated.

Referring to FIG. 8, a display device 900 according to the examples of the present disclosure may include a substrate SUB, a driving circuit layer DCL, a light emitting diode layer EDL, an encapsulation layer ENCAP, and a touch sensor layer TSL.

According to the example, the display device 900 may include a first bumpy portion BMP1_2 disposed in the non-active area NA. For example, the first bumpy portion BMP1_2 may be defined to include a bumpy pattern formed on a surface of at least a part of the plurality of insulating layers included in the display device 900. An adhesive strength between the plurality of insulating layers included in the display device 900 in the outer peripheral portion of the display device 900 in which the bumpy pattern is formed by the first bumpy portion BMP1_2, for example, in the non-active area NA may be enhanced. Accordingly, in the display device 900 according to the examples of the present disclosure, the film lifting phenomenon and a loss of the insulating layer thereby in the outer peripheral portion, for example, in the non-active area NA may be suppressed.

To be more specific, as illustrated in FIG. 8, among the plurality of insulating layers included in a driving circuit layer DCL, an insulating layer disposed on the top, for example, the second planarization layer PNL2 may include a bumpy pattern which is formed in an area in which the first bumpy portion BMP1_2 is formed. For example, the bumpy pattern may be formed on an upper surface of the second planarization layer PNL2 in the non-active area NA. For example, the bumpy pattern formed on the upper surface of the second planarization layer PNL2 in the non-active area NA may include at least one protruding portion and at least one dented portion. Accordingly, as described with reference to FIG. 3, the bank BNK may include a bumpy pattern formed in an area in which the first bumpy portion BMP1_2 is formed. For example, the bumpy pattern may be formed on a lower surface of the bank BNK in the non-active area NA.

According to the example, a bank BNK disposed in the non-active area NA, among banks BNK included in the display device 900 of FIG. 8 may be disposed in a dented portion of a bumpy pattern formed on an upper surface of the second planarization layer PNL2. That is, the bank BNK disposed in the non-active area NA may be disposed so as not to overlap the protruding portion of the bumpy pattern formed on the upper surface of the second planarization layer PNL2. Accordingly, the bank BNK compensates for the dented portion of the bumpy pattern formed on the upper surface of the second planarization layer PNL2 so that the second planarization layer PNL2 and the bank BNK provide a flat planar surface (or plane) in the non-active area NA. That is, a plane defined by the upper surface of the second planarization layer PNL2 and the upper surface of the bank BNK in the non-active area NA may be flat.

Further, the first inorganic encapsulation layer PAS1 may include a bumpy pattern formed in an area in which the first bumpy portion BMP1_2 is formed. For example, the bumpy pattern may be formed on an upper surface of the first inorganic encapsulation layer PAS1 in the non-active area NA. For example, the bumpy pattern formed on the upper surface of the first inorganic encapsulation layer PAS1 in the non-active area NA may include at least one protruding portion and at least one dented portion. Accordingly, the adhesive strength between the insulating layers may be enhanced by the first inorganic encapsulation layer PAS1.

In this case, as described above, the bank BNK compensates for the dented portion of the bumpy pattern formed on the upper surface of the second planarization layer PNL2 so that a flat upper surface is provided by the second planarization layer PNL2 and the bank BNK. Therefore, the lower surface of the first inorganic encapsulation layer PAS1 in the non-active area NA may have a flat plane.

As described above, according to the examples of the present disclosure, a display device may include a bumpy pattern which is formed on a surface of at least a part of a plurality of insulating layers which are disposed on a non-active area and/or an active area and is included in the display device. Therefore, in the non-active area and/or the active area, an adhesive strength between the plurality of insulating layers may be enhanced.

Accordingly, in the display device according to the examples of the present disclosure, a film lifting phenomenon and a loss of an insulating layer caused thereby may be suppressed.

The examples of the present disclosure can also be described as follows:

According to a first aspect of the present disclosure, there is provided a display device. The display device includes: a substrate which includes an active area of the display device and a non-active area of the display device excluding the active area; a driving circuit layer which is disposed on the substrate, the driving circuit layer including: at least one transistor disposed on the active area; and a plurality of insulating layers which are sequentially disposed on the substrate; a light emitting diode layer which is disposed on the driving circuit layer, the light emitting diode layer including: a light emitting diode which is connected to the at least one transistor and is disposed on the active area; and a bank which defines an opening area overlapping the light emitting diode; and an encapsulation layer which is disposed on the light emitting diode layer. A bumpy pattern is formed on an upper surface of an insulating layer disposed on the top, among the plurality of insulating layers included in the driving circuit layer.

A bumpy pattern may be formed on an upper surface of the bank.

The encapsulation layer may include a first inorganic encapsulation layer, an organic encapsulation layer disposed on the first inorganic encapsulation layer, and a second inorganic encapsulation layer disposed on the organic encapsulation layer, and a bumpy pattern may be formed on an upper surface of the first inorganic encapsulation layer.

An upper surface of the bank may be flat.

The encapsulation layer may include a first inorganic encapsulation layer, an organic encapsulation layer disposed on the first inorganic encapsulation layer, and a second inorganic encapsulation layer disposed on the organic encapsulation layer, and an upper surface of the first inorganic encapsulation layer may be flat.

The bumpy pattern formed on the upper surface of the insulating layer disposed on the top, among the plurality of insulating layers, may include at least one protruding portion and at least one dented portion.

The bank may be disposed in the at least one dented portion and may be disposed so as not to overlap the at least one protruding portion.

A plane defined by the upper surface of the bank and the upper surface of the insulating layer disposed on the top, among the plurality of insulating layers, may be flat.

The encapsulation layer may include a first inorganic encapsulation layer, an organic encapsulation layer disposed on the first inorganic encapsulation layer, and a second inorganic encapsulation layer disposed on the organic encapsulation layer, and a bumpy pattern may be formed on an upper surface of the first inorganic encapsulation layer.

The bumpy pattern may be disposed in the non-active area, but may not be disposed in the active area.

The bumpy pattern may be disposed in the active area and the non-active area.

According to a second aspect of the present disclosure, there is provided a display device. The display device includes: a substrate which includes an active area of the display device and a non-active area of the display device excluding the active area; a driving circuit layer which is disposed on the substrate, the driving circuit layer including: at least one transistor disposed on the active area; and a plurality of insulating layers which are sequentially disposed on the substrate; a light emitting diode layer which is disposed on the driving circuit layer, the light emitting diode layer including: a light emitting diode which is connected to the at least one transistor and is disposed on the active area; and a bank which defines an opening area overlapping the light emitting diode; and an encapsulation layer which is disposed on the light emitting diode layer. A bumpy pattern is formed on a lower surface of the bank.

The bumpy pattern may be formed on the lower surface of the bank in the non-active area.

A bumpy pattern may be formed on an upper surface of an insulating layer disposed on the top, among the plurality of insulating layers included in the driving circuit layer.

A bumpy pattern may be formed on an upper surface of the bank.

The encapsulation layer may include a first inorganic encapsulation layer, an organic encapsulation layer disposed on the first inorganic encapsulation layer, and a second inorganic encapsulation layer disposed on the organic encapsulation layer, and a bumpy pattern may be formed on a lower surface of the first inorganic encapsulation layer.

A bumpy pattern may be formed on an upper surface of the first inorganic encapsulation layer.

An upper surface of the bank may be flat.

The encapsulation layer may include a first inorganic encapsulation layer, an organic encapsulation layer disposed on the first inorganic encapsulation layer, and a second inorganic encapsulation layer disposed on the organic encapsulation layer, and an upper surface of the first inorganic encapsulation layer may be flat.

The encapsulation layer may include a first inorganic encapsulation layer, an organic encapsulation layer disposed on the first inorganic encapsulation layer, and a second inorganic encapsulation layer disposed on the organic encapsulation layer, and a bumpy pattern may be formed on an upper surface of the first inorganic encapsulation layer.

Although the examples of the present disclosure have been described in detail with reference to the accompanying drawings, the present disclosure is not limited thereto and may be embodied in many different forms without departing from the technical concept of the present disclosure. Therefore, the examples of the present disclosure are provided for illustrative purposes only but not intended to limit the technical concept of the present disclosure. The scope of the technical concept of the present disclosure is not limited thereto. Therefore, it should be understood that the above-described examples are illustrative in all aspects and do not limit the present disclosure. The protective scope of the present disclosure should be construed based on the following claims, and all the technical concepts in the equivalent scope of the present disclosure thereof should be construed as falling within the scope of the present disclosure.

What is claimed is:

1. A display device, comprising:
a substrate which includes an active area of the display device and a non-active area of the display device excluding the active area;
a driving circuit layer which is disposed on the substrate, the driving circuit layer including:
at least one transistor disposed on the active area; and
a plurality of insulating layers which are sequentially disposed on the substrate;
a light emitting diode layer which is disposed on the driving circuit layer, the light emitting diode layer including:
a light emitting diode which is connected to the at least one transistor and is disposed on the active area; and
a bank which defines an opening area overlapping the light emitting diode; and
an encapsulation layer which is disposed on the light emitting diode layer,
wherein a bumpy pattern is formed on an upper surface of an insulating layer disposed on the top, among the plurality of insulating layers included in the driving circuit layer.

2. The display device according to claim 1, wherein a bumpy pattern is formed on an upper surface of the bank.

3. The display device according to claim 1, wherein the encapsulation layer includes a first inorganic encapsulation layer, an organic encapsulation layer disposed on the first inorganic encapsulation layer, and a second inorganic encapsulation layer disposed on the organic encapsulation layer, and wherein a bumpy pattern is formed on an upper surface of the first inorganic encapsulation layer.

4. The display device according to claim 1, wherein an upper surface of the bank is flat.

5. The display device according to claim 4, wherein the encapsulation layer includes a first inorganic encapsulation layer, an organic encapsulation layer disposed on the first inorganic encapsulation layer, and a second inorganic encapsulation layer disposed on the organic encapsulation layer, and wherein an upper surface of the first inorganic encapsulation layer is flat.

6. The display device according to claim 4, wherein the bumpy pattern formed on the upper surface of the insulating layer disposed on the top, among the plurality of insulating layers, includes at least one protruding portion and at least one dented portion.

7. The display device according to claim 6, wherein the bank is disposed in the at least one dented portion and is disposed so as not to overlap the at least one protruding portion.

8. The display device according to claim 7, wherein a plane defined by the upper surface of the bank and the upper surface of the insulating layer disposed on the top, among the plurality of insulating layers, is flat.

9. The display device according to claim 7, wherein the encapsulation layer includes a first inorganic encapsulation layer, an organic encapsulation layer disposed on the first inorganic encapsulation layer, and a second inorganic encapsulation layer disposed on the organic encapsulation layer, and a bumpy pattern is formed on an upper surface of the first inorganic encapsulation layer.

10. The display device according to claim 1, wherein the bumpy pattern is disposed in the non-active area, but is not disposed in the active area.

11. The display device according to claim 1, wherein the bumpy pattern is disposed in the active area and the non-active area.

12. A display device, comprising:
a substrate which includes an active area of the display device and a non-active area of the display device excluding the active area;
a driving circuit layer which is disposed on the substrate, the driving circuit layer including:
at least one transistor disposed on the active area; and
a plurality of insulating layers which are sequentially disposed on the substrate;
a light emitting diode layer which is disposed on the driving circuit layer, the light emitting diode layer including:
a light emitting diode which is connected to the at least one transistor and is disposed in the active area; and
a bank which defines an opening overlapping the light emitting diode; and
an encapsulation layer which is disposed on the light emitting diode layer,
wherein a bumpy pattern is formed on a lower surface of the bank.

13. The display device according to claim 12, wherein a bumpy pattern is formed on an upper surface of an insulating layer disposed on the top, among the plurality of insulating layers included in the driving circuit layer.

14. The display device according to claim 13, wherein a bumpy pattern is formed on an upper surface of the bank.

15. The display device according to claim 14, wherein the encapsulation layer includes a first inorganic encapsulation layer, an organic encapsulation layer disposed on the first inorganic encapsulation layer, and a second inorganic encapsulation layer disposed on the organic encapsulation layer, and wherein a bumpy pattern is formed on a lower surface of the first inorganic encapsulation layer.

16. The display device according to claim 15, wherein a bumpy pattern is formed on an upper surface of the first inorganic encapsulation layer.

17. The display device according to claim 14, wherein an upper surface of the bank is flat.

18. The display device according to claim 17, wherein the encapsulation layer includes a first inorganic encapsulation layer, an organic encapsulation layer disposed on the first inorganic encapsulation layer, and a second inorganic encapsulation layer disposed on the organic encapsulation layer, and wherein an upper surface of the first inorganic encapsulation layer is flat.

19. The display device according to claim 17, wherein the encapsulation layer includes a first inorganic encapsulation layer, an organic encapsulation layer disposed on the first inorganic encapsulation layer, and a second inorganic encapsulation layer disposed on the organic encapsulation layer, and wherein a bumpy pattern is formed on an upper surface of the first inorganic encapsulation layer.

20. The display device according to claim 12, wherein the bumpy pattern is formed on the lower surface of the bank in the non-active area.
